(19) United States
(12) Patent Application Publication
(10) Pub. No.: US 2013/0081664 A1
(43) Pub. Date: Apr. 4, 2013

(54) Thermoelectric Layout

(71) Applicants: Mark C. Woods, Allen, TX (US); Overton L. Parish, IV, Frisco, TX (US)

(72) Inventors: Mark C. Woods, Allen, TX (US); Overton L. Parish, IV, Frisco, TX (US)

(21) Appl. No.: 13/631,138

(22) Filed: Sep. 28, 2012

Related U.S. Application Data
(60) Provisional application No. 61/541,536, filed on Sep. 30, 2011.

(51) Int. Cl. H01L 35/32

(52) U.S. Cl. CPC H01L 35/32
USPC 136/204; 136/203

(57) ABSTRACT

In one embodiment, a thermoelectric device includes a plurality of thermoelectric elements arranged in a substantially polygonal pattern. The substantially polygonal pattern has more than four sides. The device includes a first dielectric plate coupled to the thermoelectric elements and a second dielectric plate coupled to the thermoelectric elements. The device also includes a first set of fins coupled to the first dielectric plate and a second set of fins coupled to the second dielectric plate.

### CROSS-REFERENCE TO RELATED APPLICATION

This application claims the benefit of priority under 35 U.S.C. §119(e) of U.S. Provisional Application Ser. No. 61/541,536, entitled “IMPROVED THERMOELECTRIC LAYOUT,” filed Sep. 30, 2011, the entire content of which is incorporated herein by reference.

### TECHNICAL FIELD

This disclosure relates generally to thermoelectric devices and more particularly to an improved thermoelectric layout.

### BACKGROUND

The basic theory and operation of thermoelectric devices has been developed for many years. Presently available thermoelectric devices used for heating and cooling applications typically include an array of thermoelectric elements which operate in accordance with the Peltier effect.

Thermoelectric devices may be described as essentially small heat pumps which follow the laws of thermodynamics in the same manner as mechanical heat pumps, refrigerators, or any other apparatus used to transfer heat energy. A principal difference is that thermoelectric devices function with solid state electrical components (thermoelectric elements or thermocouples) as compared to more traditional mechanical/fluid heating and cooling components. Mechanical stresses may affect thermoelectric devices, such as thermally-induced shearing. Such stresses may cause one or more components of a thermoelectric device to fail.

### SUMMARY

In one embodiment, a thermoelectric device includes a plurality of thermoelectric elements arranged in an octagonal layout. The device includes a first dielectric plate in an octagonal shape coupled to the thermoelectric elements and a second dielectric plate coupled to the thermoelectric elements. The device includes a first set of fins in an octagonal shape coupled to the first dielectric plate. The device includes a second set of fins coupled to the second dielectric plate.

Depending on the specific features implemented, particular embodiments may exhibit some, none, or all of the following technical advantages. Regions of stress or fracturing in thermoelectric elements may be reduced or eliminated. Temperature differences between dielectric plates may be reduced. Other technical advantages will be readily apparent to one skilled in the art from the following figures, description and claims.

### BRIEF DESCRIPTION OF THE DRAWINGS

Reference is now made to the following description taken in conjunction with the accompanying drawings, wherein like reference numbers represent like parts and which:

FIGS. 1A and 1B illustrate example embodiments of a temperature control system that includes a cooling unit coupled to a temperature-controlled item via a network of hoses according to the present disclosure;

FIGS. 2A and 2B illustrate example embodiments cooling systems in a parallel flow configuration and a cross flow configuration;

FIGS. 3A and 3B illustrate exploded views of example embodiments of components in the cooling systems illustrated in FIGS. 2A and 2B;

FIG. 4A illustrates one embodiment of a thermoelectric circuit on a dielectric plate;

FIG. 4B illustrates one embodiment of a dielectric plate in an octagonal shape;

FIG. 5 illustrates one embodiment of a dielectric plate that includes traces;

FIG. 6 illustrates one embodiment of a frame;

FIG. 7 illustrates another embodiment of a frame.

### DETAILED DESCRIPTION

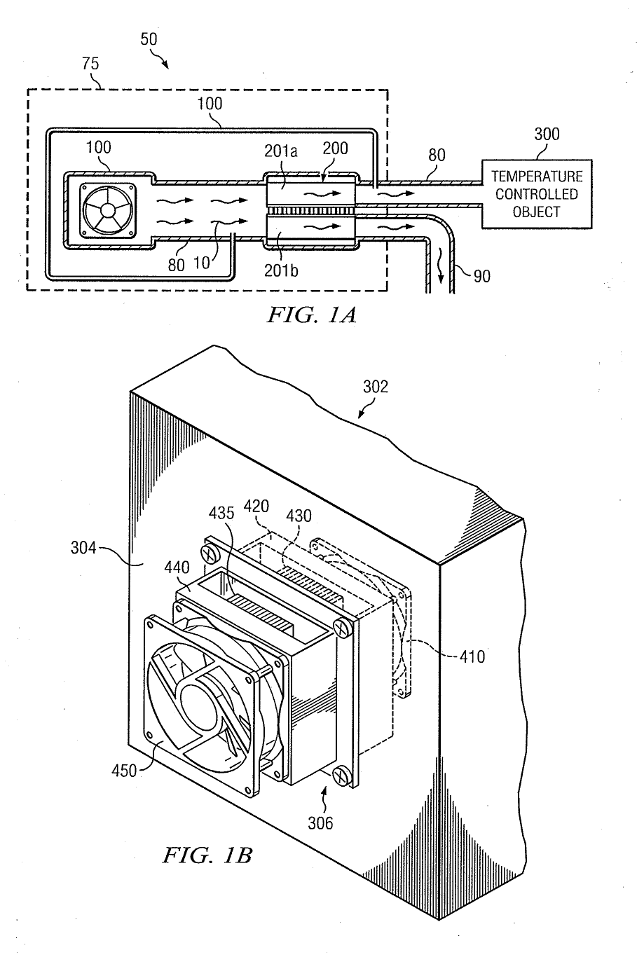

FIG. 1A illustrates an example temperature control system 50 that includes a cooling unit 75 coupled to a temperature-controlled object 300. Cooling unit 75 generally includes a temperature control device 200 operable to generate or absorb heat and a circulation device 100 operable to circulate flowable medium 10 across temperature control device 200.

Depending upon the design and application of temperature control system 50, flowable medium 10 could be, for example, a gas such as air, or a liquid such as water. In particular embodiments, temperature control system 50 could be a self-contained unit wherein a defined amount of flowable medium 10 is completely contained within a confined reservoir and is re-circulated through temperature control system 50. In other embodiments, temperature control system 50 could be an open unit wherein flowable medium 10 is freely exchanged with the surrounding environment. In still other embodiments temperature control system 50 may be a hybrid unit where a portion of flowable medium 10 (e.g., the portion intended for temperature controlled object 300) is re-circulated through temperature control system 50, while another other portion of flowable medium 10 (e.g., the portion that conducts waste energy away from temperature control device 200) is exchanged with the surrounding environment.

As will be explained in further detail below, temperature control device 200 may alter the temperature of flowable medium 10 as it passes through temperature control device 200. For example, in certain applications, temperature control device 200 may cool the portion of flowable medium 10 directed to temperature controlled object 300. After being cooled by temperature control device 200, flowable medium 10 may be circulated through temperature-controlled object 300 to cool temperature-controlled object 300. In particular embodiments where flowable medium 10 is a gas, cooling unit 75 may further include a conduit or wick 81 for redirecting condensed moisture from the output of temperature control device 200 into the hot side air intake of temperature control device 200 to pre-cool the air entering on the hot side of temperature control device 200.

Circulation device 100 may be any component of hardware or combination of such components capable of circulating flowable medium 10 throughout temperature control system 50. As an example and not by way of limitation, circulation device 100 could be a fan in embodiments where flowable medium 10 is a gas, or a pump in embodiments where flowable medium 10 is a liquid.

Circulation device 100 may circulate flowable medium 10 throughout temperature control system 50 via a network of hoses 80. A hose 80 may be any type of conduit capable conveying flowable medium 10 from one component of temperature control system 50 to another. As an example and not by way of limitation, a hose 80 may be a piece of flexible tubing spanning between two components of temperature control system 50. One of ordinary skill in the art will appreciate that the configuration of hoses 80 may be determined by the application for which temperature control system 50 is being used. For example, if temperature control system 50 is a self contained unit, hoses 80 will be configured to provide a re-circulating path for some or all of flowable medium 10. However, if temperature control system 50 is an open unit, hoses 80 may include one or more ports 90 for exchanging flowable medium 10 with the surrounding environment.

Depending upon design, a first side 201a of temperature control device 200 may be configured to condition the temperature of the portion of flowable medium 10 being circulated into temperature-controlled object 300, while a second side 201b of temperature control device 200 may be configured to dissipate unwanted thermal energy from temperature control device 200. For example if temperature control system 50 is an open unit, the portion of flowable medium 10 circulated through second side 201b may be expelled into the surrounding environment through an exhaust port 90.

Depending upon the mode of operation of temperature control device 200, flowable medium 10 may either raise or lower the temperature of temperature-controlled object 300. Temperature-controlled object 300 may be any type of item such as, for example, a bed, theater chair, office chair, vest, suit of body armor, or ice chest. In one particular embodiment, temperature control system 50 could represent a temperature-controlled suit of body armor capable of keeping a soldier from overheating in the field of combat.

FIG. 1B illustrates one embodiment of system 302 that includes cooling apparatus 306 coupled to housing 304 such that a portion of cooling apparatus 306 is enclosed within housing 304. Housing 304 may enclose an object, device, or system that creates heat and would benefit from cooling. Cooling apparatus 306 may include fan 410, housing 420, and fins 430 (included in a cold-side of cooling apparatus 306) that are enclosed in housing 304. This may be the cold-side of a thermoelectric cooling system implemented by cooling apparatus 360. Housing 440 and fan 450 (included in a hot-side of cooling apparatus 306) may be located outside of housing 304.

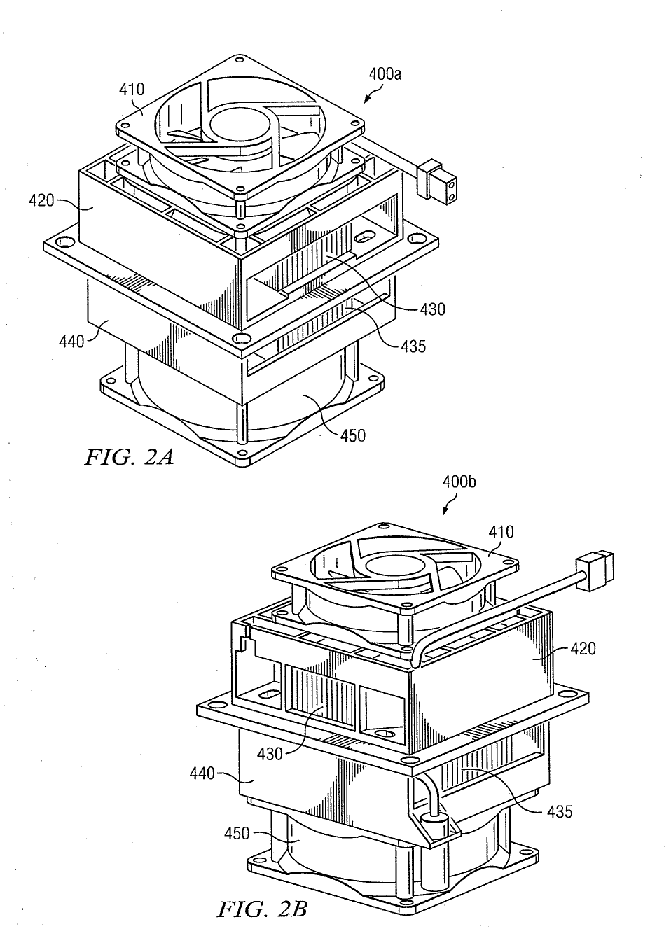

FIGS. 2A and 2B illustrate embodiments of two cooling systems (400a and 400b) in a parallel flow configuration (400a) and a cross flow configuration (400b). In some embodiments, cooling systems 400a and/or 400b may be used to implement cooling apparatus 306 of FIG. 1B. Cooling systems 400a-b include fan 410 coupled to housing 420 that includes fins 430. Housing 420 is coupled to housing 440 which includes fins 435. Fan 450 is coupled to housing 440. In operation, cooling systems 400a-b may be configured to draw heat from components that may be coupled to or near fan 410 and cause the heat to be transferred through housing 420 and fins 430. Thermoelectric elements may be situated at the junction of housing 420 and 430 which may allow the heat to be transferred to components within housing 440. This may be facilitated by fins 435. Fan 450 may remove heat from components in housing 440. One difference between cooling system 400a and cooling system 400b may be the orientation of the openings on housing 420 and 440.

As illustrated in cooling system 400a the openings of housing 420 and 440 are in the same vertical plane whereas the openings of housing 420 and housing 440 in cooling system 400b are 90 degrees apart. In some embodiments, insulation (not depicted in FIGS. 2A and 2B) may be placed completely around cooling system 400b except for the openings of housing 420 and housing 440 and the openings of fans 410 and 450. In contrast, insulation may not be placed on one side of cooling system 400a because it may be preferable not to have insulation covering the openings on housing 420 and housing 440.

In some embodiments, when cooling systems 400a and 400b are attached to an appropriate source of power (e.g., a DC battery), one side of each of cooling systems 400a and 400b will generate heat and the other side of each of cooling systems 400a and 400b will absorb heat. The polarity of the current from the power source determines which side of cooling systems 400a and 400b absorbs heat and which side generates heat. Fans 410 and 450 may circulate a flowable medium across cooling systems 400a and 400b, fins 430 and 435 may aid in transferring thermal energy into or out of cooling systems 400a and 400b by increasing the amount of surface area over which cooling systems 400a and 400b may dissipate thermal energy into or absorb thermal energy from the flowable medium.

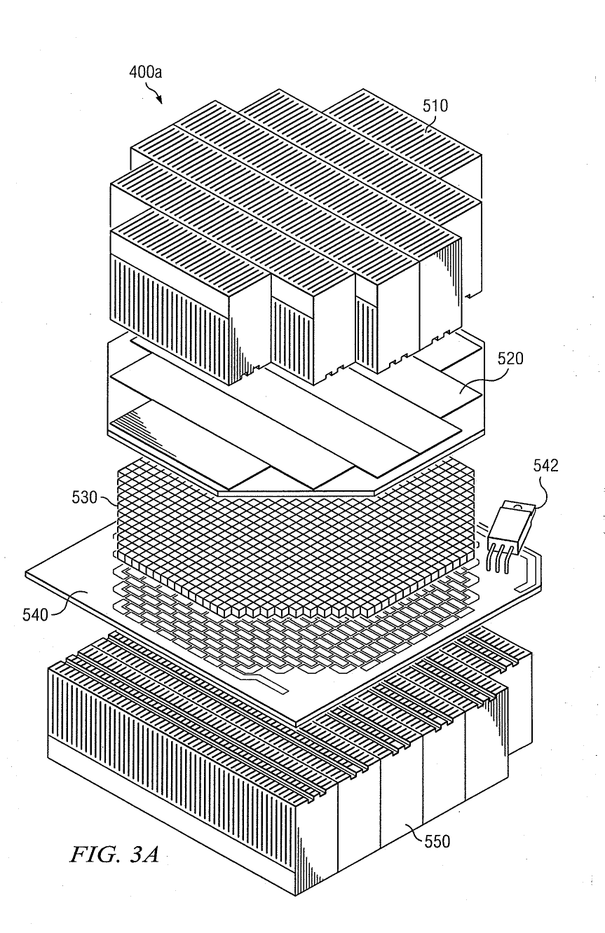

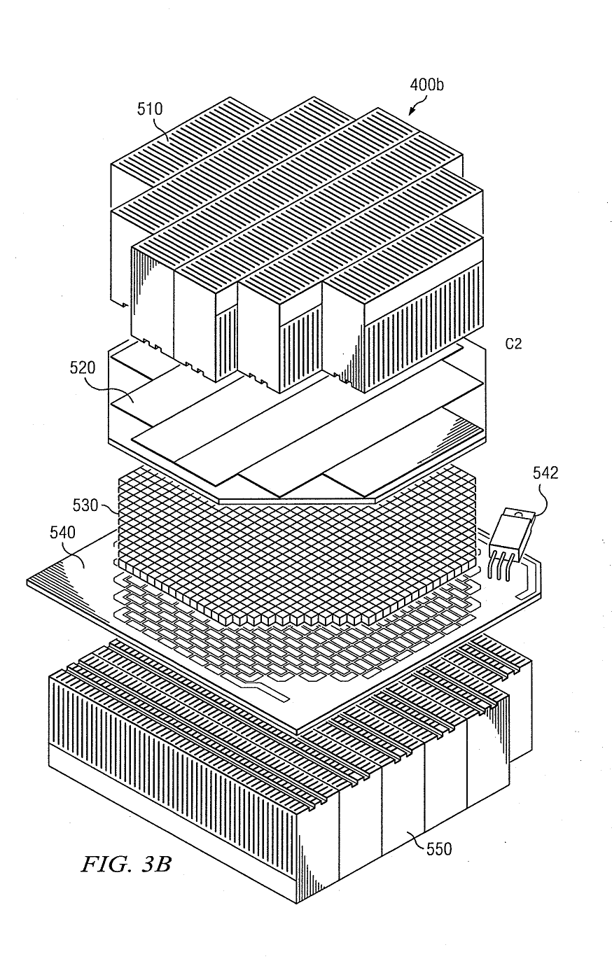

FIGS. 3A and 3B are exploded views of components in cooling systems 400a and 400b in some embodiments. Fins 510 are coupled to dielectric plate 520 (e.g., using solder). Dielectric plate 520 is coupled to thermoelectric elements 530. Thermoelectric elements 530 are coupled dielectric plate 540. Fins 550 are coupled to dielectric plate 540 (e.g., using solder).

In some embodiments, dielectric plate 520 may have a polygonal shape or a circular shape. For example, the shape of dielectric plate 520 may be hexagonal, octagonal, pentagonal or other polygonal shapes with four or more sides. Dielectric plate 520 may have metallizations patterns that may be used to solder fins 510 to dielectric plate 520. Dielectric plate 520 may not have metallizations and fins 510 may be coupled to dielectric plate 520 using glue or epoxy. Dielectric plates 520 and 540 may have interconnect patterns on the surfaces that interface with thermoelectric elements 530 such that thermoelectric elements 530 may be coupled to one another in a manner that produces a thermoelectric effect. For example, thermoelectric elements 530 may be coupled such that applying electricity to may cause one side of thermoelectric elements 530 to be cold and another side to be hot. Thermoelectric elements 530 may also be arranged in a hexagonal, octagonal, pentagonal, or other polygonal patterns with more than four sides to correspond with dielectric plate 520. Fins 510 may also be in a polygonal shape corresponding to dielectric plate 520. Dielectric plate 540 and fins 550 may or may not be in a polygonal shape that corresponds with dielectric plate 520. In some embodiments, dielectric plate 520 may be implemented using a ceramic plate (e.g., ranging in thickness from 1 to 3 millimeters).

In some embodiments, thermoelectric elements 530 may be fabricated from dissimilar semiconductor materials such as N-type and P-type thermoelectric elements. Thermoelectric elements 530 are typically configured in a generally alternating N-type element to P-type element arrangement and typically include an air gap disposed between adjacent N-type and P-type elements. In some embodiments, thermoelectric elements 530 with dissimilar characteristics are connected electrically in series and thermally in parallel using metallized dielectric plates 520 and 540. Examples of material used to implement thermoelectric elements 530 include lead telluride (PbTe), lead germanium telluride (PbGeTe), TAGS alloys (such as (GeTe)_{0.85}(AgSbTe₂)_{0.15}), bismuth telluride (Bi₂Te₃), and skutterudites.

In some embodiments, using a polygonal shape with more than four sides (e.g., an octagon or a decagon) may reduce thermally-induced shearing at the points where dielectric plate 520 is coupled to thermoelectric elements 530. For example, as a result of the thermoelectric operation, dielectric plates 520 and 540 may be at very different temperatures which induces physical shearing since one of the plates will be expanding and the other will be contracting. As an example, the octagonal shape of dielectric plate 520 thermoelectric element pattern 530 may reduce the chance of element fracture due to effect of the shearing on the points of contact between dielectric plate 520 and thermoelectric elements 530 by reducing the maximum distance between the points of contact and the center of dielectric plate 520 as compared to a n element pattern that was square or rectangular in shape. In some embodiments, dielectric plate 540 may include power field-effect transistor (FET) 542 that may control the provision of power to cooling systems 400a and/or 400b. Placement of power FET 542 may reduce or minimize the impact of heat generation and electromagnetic emissions from power FET 542.

In some embodiments, fins 510 and 550 may be any fixture capable of increasing the surface area over which cooling systems 400a and/or 400b may exchange thermal energy with a flowable medium (e.g., air). For example, fins 510 and 550 may be a zipped or stacked fin heat exchanger comprising a plurality of closely-spaced fins separated from one another by a series of spaces. Each fin may include one or more flanges or other features operable to interlock the plurality of fins together into a single, unitary array. For example, flanges may be a series of frusto-conically-shaped perforations in fins 510 and 550 that are nested inside one another to link each of the individual fins together. Fins 510 and 550 may include a plurality of zipped fin structures, with each having a flat bottom coupled to a plurality of parallel fins.

In other embodiments, fins 510 and/or 550 may be a folded fin structure comprising a single sheet of material (e.g., copper) that has been consecutively folded over onto itself to create a single array of closely spaced fins. Each fin may include a lateral (e.g., generally L-shaped) fold at one end that, when aggregated together, form a flat. Fins 510 and 550 may be constructed out of a thermally conductive material such as copper, aluminum or other metal. However, any suitable thermally conductive material may be used.

In cases where flowable medium is a gas such as air, due to the tight fin pitch (e.g., close fin spacing) associated with zipped or folded fin structures, strong capillary forces may fill spaces in fins 510 and/or 550 with moisture at sub-ambient temperatures. The accumulation of moisture may impede the flow of flowable medium through cooling systems 400a and/or 400b, thereby reducing its efficiency. In order to counteract the tendency of spaces in fins 510 and/or 550 to fill with moisture, a hydrophobic coating may be applied to or incorporated into fins 510 and/or 550. The hydrophobic coating may be any compound or formula capable of preventing or retarding the accumulation of moisture on fins 510 and/or 550 during operation of temperature cooling systems 400a and/or 400b. As an example and not by way of limitation, the hydrophobic coating may be SILANE manufactured by Dow Corning, Inc.

Fins 510 and 550 may be coupled to cooling systems 400a and 400b using any suitable method or mechanism. In particular embodiments, fins 510 and 550 may be coupled using any compound or fixture, or combination of compounds and fixtures, operable to provide a thermally conductive bond between fins 510 and 550 and cooling systems 400a and 400b. As an example and not by way of limitation, coupling media may be solder or thermally conductive epoxy. Thus, fins 510 and/or 550 may be soldered or epoxied directly to cooling systems 400a and/or 400b.

In some embodiments, cooling systems 400a and/or 400b may exhibit one or more technical advantages. For example, cooling systems 400a and/or 400b may be used to provide a temperature control device that may be well suited for the enclosure cooling and personal cooling market due to one or more of: being light weight, compact size, high surface area, high coefficient of performance (“COP”), high volume manufacturing processes (e.g., providing lower costs), low weight, and low volume. As another example, fins 510 and 550 included in a temperature control device may be sufficiently small to minimize mechanical stress imposed on a joint between the bottom of fins 510 and 550 and dielectric plates 520 and 540 that may be caused by coefficient of thermal expansion (CTE) mismatch between these fins 510 and dielectric plate 520 as well as fins 550 and dielectric plate 540.

In some embodiments, the octagonal shape (or other polygonal shapes with greater than four sides) of cooling systems 400a and/or 400b may provide one or more advantages. Square thermoelectric coolers may have been limited in size to approximately 50 mm×50 mm, due to mechanical stresses from mismatched coefficients of thermal expansion (e.g., between fins and dielectric plates) which can cause damage. Such stresses may be highest at the periphery of thermoelectric devices, in particular at the corners of square coolers. Fracturing of thermoelectric elements at the corners is a common failure mode in large square and rectangular thermoelectric coolers. Maximizing the area-to-perimeter ratio of the thermoelectric circuit enables the cooler to be built larger without undue risk of failures due to mismatched coefficients of thermal expansion. The octagonal (or other polygonal shapes with greater than four sides) layout of cooling systems 400a and/or 400b discussed above may reduce or eliminate regions of stress and vulnerable corner thermoelectric elements. It may also offer a shape or layout that is manufacturing-friendly.

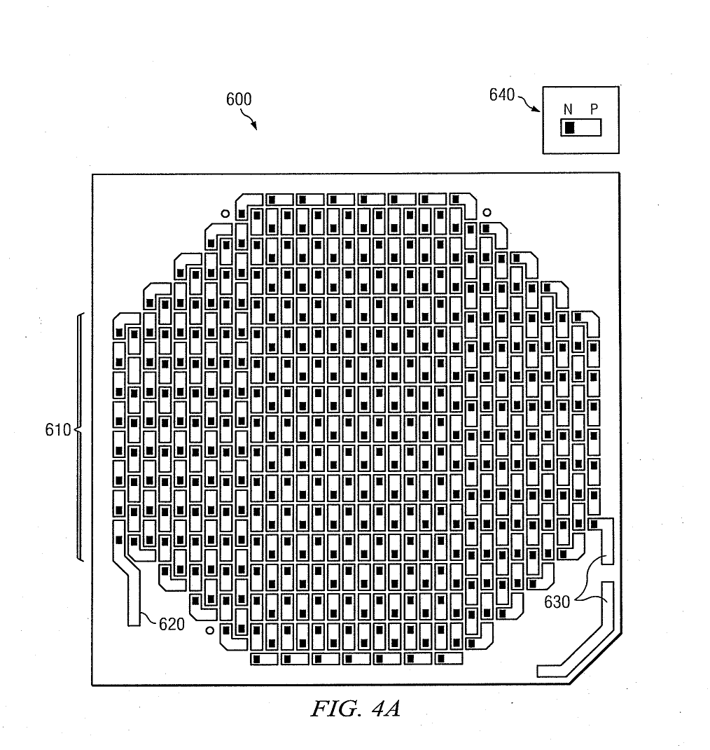

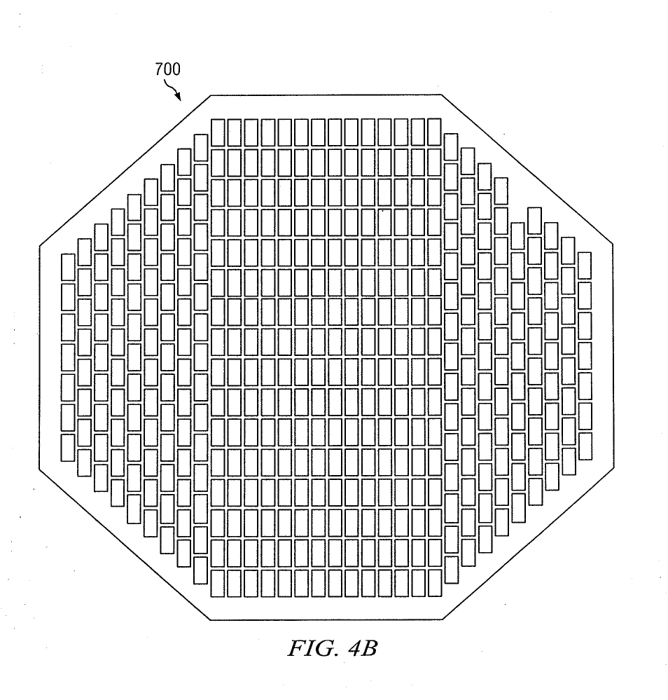

FIG. 4A illustrates one embodiment of a thermoelectric circuit on dielectric plate 600. Dielectric plate 600 may include interconnects 610 that couple thermoelectric elements as illustrated in FIG. 4A. Interconnects 610 may be configured in an octagonal shape. Other polygonal shapes may be used such as pentagonal, hexagonal or other polygonal shapes with more than four sides. As illustrated by legend 640, interconnects 610 may couple N-type and P-type thermoelectric elements. Dielectric plate 600 also includes positive lead 630 and negative lead 620 that may be coupled to a power source. In some embodiments, dielectric plate 540 of FIG. 3A may be implemented using dielectric plate 600.

FIG. 4B illustrates one embodiment of dielectric plate 700 that is in an octagonal shape. Other shapes may be used for dielectric plate 700 including pentagonal, hexagonal, or other polygonal shapes with four or more sides. Dielectric plate 700 includes a circuit pattern that may be used to couple a set of thermal electric elements such as thermoelectric elements 530 of FIG. 3A. Dielectric plate 700 may be an example of an implementation of dielectric plate 520 of FIGS. 3A and 3B.

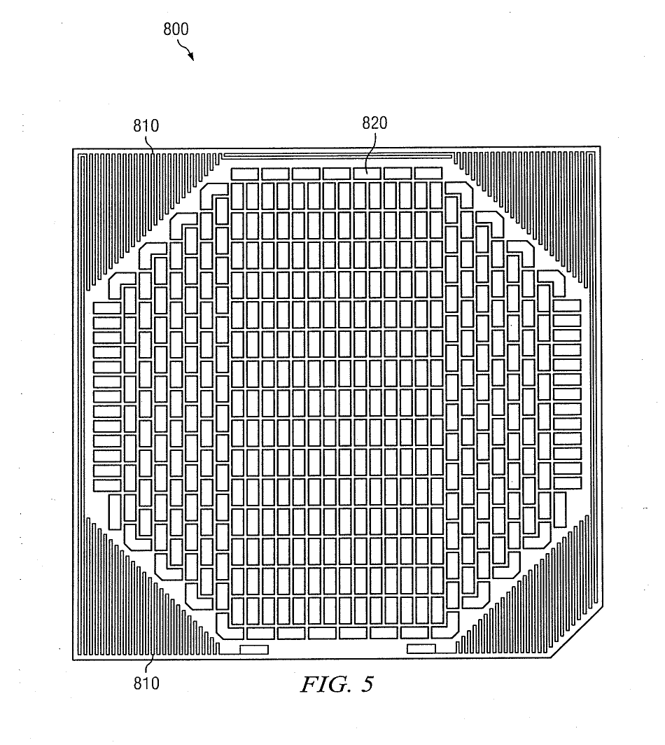

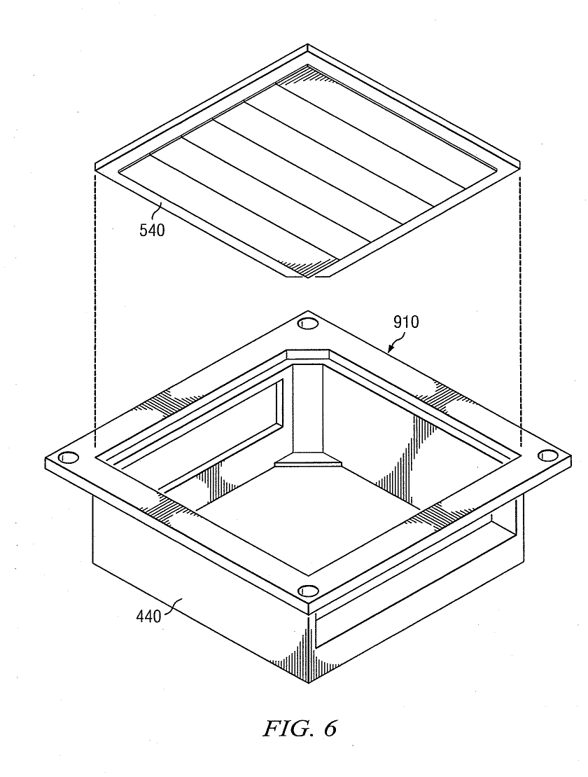

FIG. 5 illustrates one embodiment of dielectric plate 800 that includes traces 810. In some embodiments, dielectric plate 800 may be used to implement dielectric plate 540 of FIGS. 3A and 3B. Dielectric plate 800 may include traces 810 and interconnects 820. Interconnects 820 may be used to couple thermal electric elements into a circuit. Interconnects 820 may be in a octagonal shape as illustrated in FIG. 5. In some embodiments, interconnects 820 may be configured in other polygonal shapes with more than four sides such as a decagon, a pentagon, or a hexagon. In some embodiments, traces 810 may be resistive elements that are used to help reduce a temperature difference between multiple dielectric plates. For example, if dielectric plate 800 is used to implement dielectric plate 540, traces 810 may help to reduce the temperature difference between dielectric plate 520 and dielectric plate 540 when cooling system 400a or 400b is operating in a reverse mode. In some embodiments, traces 810 may enable heating of an associated enclosure or system beyond what may be delivered via reverse-polarity operation within the operating limits of the thermoelectric device that include traces 810. This ability to generate excess heat could be used, for example, in sterilization functions.

In some embodiments, interconnects that may be present on dielectric plates 600, 700, and 800 may be composed of an electrically and thermally conductive material such as copper. Depending upon design, interconnects may be a patterned metallization formed on the interior surfaces of dielectric plates 600, 700, and 800 using any suitable deposition process. Also, depending upon the composition of thermoelectric elements coupled to dielectric plates 600, 700, and 800 and interconnects, a diffusion barrier metallization may be applied to the ends of the thermoelectric elements to provide a surface for soldering and to prevent chemical reactions from occurring between the interconnects and the thermoelectric elements. For example, the diffusion barrier may be needed if the interconnects are composed of copper. The diffusion barrier may comprise nickel or other suitable barrier material (e.g., molybdenum).

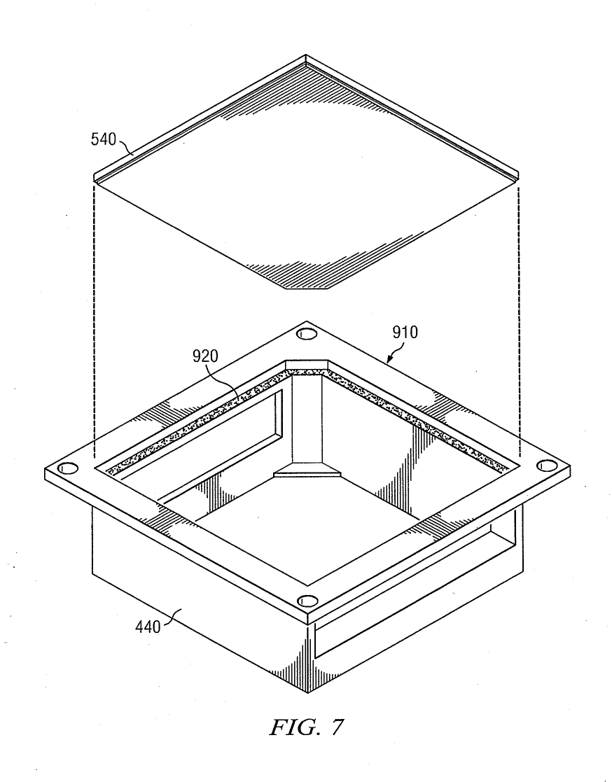

FIG. 6 illustrates one embodiment of frame 910 that may be used to house dielectric plate 540. Adhesive or epoxy may be used to secure dielectric plate 540 to frame 910. Dielectric plate 540 may be secured to frame 910 in a manner that the ingress of dust and/or moisture may be reduced or prevented. Frame 910 may also be secured to housing 440 as illustrated. For example, screws or other mechanical securing devices or structures may be used at the periphery of frame 910 to secure it to housing 440. Dielectric plate 540 may have an external surface that is metalized (e.g., nearly 100% metalized) and in contact with frame 910. Frame 910 may be metalized. This may provide the ability to contain emissions which may result in electromagnetic interference (EMI). For example, a power field-effect transistor (FET) (such as power FET 542) may produce electromagnetic emissions that may be mitigated using frame 910.

FIG. 7 illustrates one embodiment of frame 910 that may be used to house dielectric plate 540 whose external surface may have a continuous layer of metallization that extends at or near to the edge of plate 540. Frame 910 may be formed from an electrically conductive material and may be electrically coupled with dielectric plate 540 via medium 920. Medium 920 may be a conductive epoxy or a similarly conductive medium. This may enable a thermoelectric device comprising dielectric plate 540 to be in electrical contract with frame 910 via an electrically conductive gasket (e.g., medium 920) to form an electromagnetic interference (EMI) containment structure.

In some embodiments, frame 910 may be formed from a material that is not an electrically conductive (e.g., plastic). Frame 910 may be partially or totally coated with an electrically conductive paint, tape, or similar coating in order to be electrically coupled with dielectric plate 540. This may allow for an EMI containment structure to be formed.

Although several embodiments have been illustrated and described in detail, it will be recognized that modifications and substitutions are possible without departing from the spirit and scope of the appended claims.

What is claimed is:

1. A thermoelectric device, comprising:
a plurality of thermoelectric elements arranged in a substantially polygonal pattern, the substantially polygonal pattern having more than four sides;
a first dielectric plate coupled to the thermoelectric elements;
a second dielectric plate coupled to the thermoelectric elements;
a first set of fins coupled to the first dielectric plate; and
a second set of fins coupled to the second dielectric plate.

2. The device of claim 1, wherein the second dielectric plate comprises resistive traces.

3. The device of claim 1, further comprising:
a frame housing the second dielectric plate such that the frame and the second dielectric plate are electrically coupled.

4. The device of claim 1, wherein the first dielectric plate has a substantially polygonal shape corresponding to the substantially polygonal pattern, the substantially polygonal shape having more than four sides.

5. The device of claim 1, wherein the first set of fins has a substantially polygonal shape corresponding to the substantially polygonal pattern, the substantially polygonal shape having more than four sides.

6. The device of claim 1, wherein the substantially polygonal pattern is a substantially octagonal pattern.

7. The device of claim 1, further comprising a power field-effect transistor arranged on the second dielectric plate.

8. The device of claim 1, wherein the second dielectric plate comprises a metalized surface.

9. A system configured to alter the temperature of an object using a flowable medium, the system comprising:
a plurality of thermoelectric elements arranged in a substantially polygonal pattern, the substantially polygonal pattern having more than four sides;
a first dielectric plate coupled to the thermoelectric elements;
a second dielectric plate coupled to the thermoelectric elements;
a first set of fins coupled to the first dielectric plate;
a second set of fins coupled to the second dielectric plate; and
a fan configured to circulate the flowable medium across the first set of fins.

10. The system of claim 9, wherein the second dielectric plate comprises resistive traces.

11. The system of claim 9, further comprising:
a frame housing the second dielectric plate such that the frame and the second dielectric plate are electrically coupled.

12. The system of claim 9, wherein the first dielectric plate has a substantially polygonal shape corresponding to the substantially polygonal pattern, the substantially polygonal shape having more than four sides.

13. The system of claim 9, wherein the first set of fins has a substantially polygonal shape corresponding to the substantially polygonal pattern, the substantially polygonal shape having more than four sides.

14. The system of claim 9, wherein the substantially polygonal pattern is a substantially octagonal pattern.

15. The system of claim 9, further comprising a power field-effect transistor arranged on the second dielectric plate.

16. The system of claim 9, wherein the second dielectric plate comprises a metalized surface.
